(19) United States
(12) Patent Application Publication
(10) Pub. No.: US 2013/0003315 A1
(43) Pub. Date: Jan. 3, 2013

(54) HEAT DISSIPATER AND PRINTED CIRCUIT BOARD MODULE

(75) Inventor: SONG-LING YANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/220,638

(22) Filed: Aug. 29, 2011

(30) Foreign Application Priority Data
Jun. 29, 2011 (CN) 201110179301.1

(51) Int. Cl. H05K 7/20

(52) U.S. Cl. 361/720; 361/704

(57) ABSTRACT

A heat dissipater and a printed circuit board module using the heat dissipater are disclosed. The heat dissipater includes at least two electrode plates and a number of rotatable charged particles between the at least two electrode plates. The at least two electrode plates are respectively connected to a positive terminal and a negative terminal of a variable power supply, and generating an alternating electric field therebetween. Each of the plurality of charged particles is made of thermal conductive material and includes a positive portion and a negative portion coupled to the positive portion.

### BACKGROUND

1. Technical Field

The present disclosure relates to a heat dissipater and a printed circuit board (PCB) module using the heat dissipater.

2. Description of Related Art

A heat sink is often used to dissipate heat generated by electronic components mounted on a printed circuit board (PCB). However, most heat sinks are made of aluminum alloy and include a number of fins. Thus, the conventional heat sinks are too bulky for use with a PCB.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of a printed circuit board module and a heat dissipater according to an exemplary embodiment.

FIG. 2 is another schematic view of the printed circuit board module of FIG. 1, showing charged particles rotated.

### DETAILED DESCRIPTION

Embodiments of the present disclosure are now described in detail, with reference to the accompanying drawings.

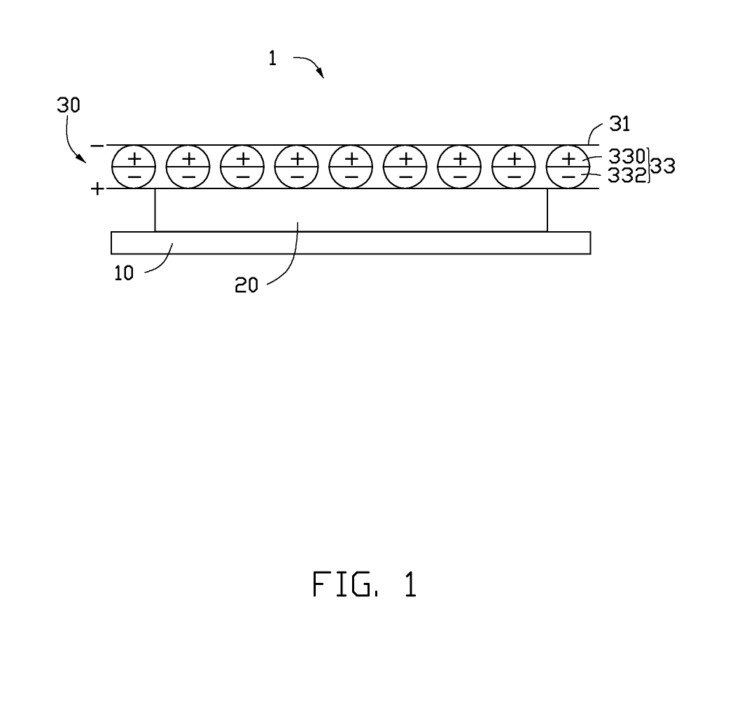

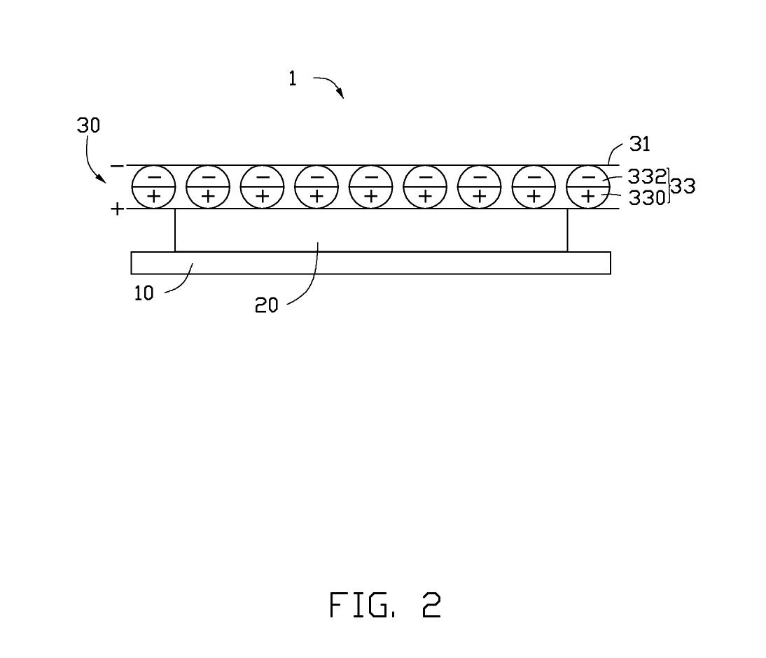

Referring to FIGS. 1-2, a printed circuit board (PCB) module 1 and a heat dissipater 30 according to an exemplary embodiment are illustrated. The printed circuit board module 1 includes a printed circuit board 10 and an electronic component 20 mounted on the printed circuit board 10. The heat dissipater 30 stays in contact with the electronic component 20 and is used to dissipate heat generated by the electronic component 20.

The heat dissipater 30 includes at least two spaced electrode plates 31 and a number of rotatable charged particles 33 between the at least two electrode plates 31. The at least two electrode plates 31 are respectively connected to a positive terminal and a negative terminal of a variable power supply (not shown), thereby allowing an alternating electric field to be generated between each two electrode plates 31. In the embodiment, the at least two electrode plates 31 are flexible electrodes or metal-plated electrodes.

The charged particles 33 are made of thermal conductive material, and can dissipate heat generated by the electronic component 20. Each charged particle includes a positive portion 330 and a negative portion 332 coupled to the positive portion 330. In the embodiment, the charged particles 33 are sphere-shaped, and the positive portion 332 and the negative portion 330 are hemisphere-shaped.

In operation, due to the alternating electric field between the electrode plates 31, the charged particles 33 therebetween are driven to rotate, thereby facilitating rapid dissipation of the heat generated by the electronic component.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A heat dissipater comprising:
at least two electrode plates respectively connected to a positive terminal and a negative terminal of a variable power supply, and configured for generating an alternating electric field therebetween; and
a plurality of rotatable charged particles between the at least two electrode plates, wherein each of the plurality of charged particles is made of thermal conductive material and comprises a positive portion and a negative portion coupled to the positive portion, wherein the plurality of rotatable charged particles is to be driven to rotate by the alternating electric field.

2. The heat dissipater as described in claim 1, wherein the at least two electrode plates are flexible electrode or metal-plated electrodes.

3. The heat dissipater as described in claim 1, wherein the plurality of charged particles are sphere-shaped, and the positive portion and the negative portion are hemisphere-shaped.

4. A printed circuit board module comprising:
a printed circuit board;
an electronic component mounted on the printed circuit board; and
a heat dissipater comprising:
at least two electrode plates respectively connected to a positive terminal and a negative terminal of a variable power supply, and generating an alternating electric field therebetween; and
a plurality of rotatable charged particles between the at least two electrode plates, wherein each of the plurality of charged particles is made of thermal conductive material and comprises a positive portion and a negative portion coupled to the positive portion, wherein the plurality of rotatable charged particles is to be driven to rotate by the alternating electric field.

5. The printed circuit board module as described in claim 4, wherein the at least two electrode plates are flexible electrode or metal-plated electrodes.

6. The printed circuit board module as described in claim 4, wherein the plurality of charged particles are sphere-shaped, and the positive portion and the negative portion are hemisphere-shaped.

7. A printed circuit board module comprising:
a printed circuit board;
an electronic component mounted on the printed circuit board; and
a heat dissipater comprising:
two electrode plates respectively connected to a positive terminal and a negative terminal of a variable power supply, and generating an alternating electric field therebetween; and
a plurality of rotatable charged particles between the two electrode plates, wherein each of the plurality of charged particles is made of thermal conductive material and comprises a positive portion and a negative portion coupled to the positive portion, wherein the plurality of rotatable charged particles is to be driven to rotate by the alternating electric field.

8. The printed circuit board module as described in claim 7 wherein the two electrode plates are flexible electrode or metal-plated electrodes.

9. The printed circuit board module as described in claim 7, wherein the plurality of charged particles are sphere-shaped, and the positive portion and the negative portion are hemisphere-shaped.
